(19) United States
(12) Patent Application Publication
(10) Pub. No.: US 2012/0091557 A1
(43) Pub. Date: Apr. 19, 2012

(54) ANTI-FUSE OF SEMICONDUCTOR DEVICE AND METHOD FOR MANUFACTURING THE SAME

(75) Inventor: Jin Hwan LEE, Icheon-si (KR)

(73) Assignee: Hynix Semiconductor Inc., Icheon (KR)

(21) Appl. No.: 13/273,789

(22) Filed: Oct. 14, 2011

(30) Foreign Application Priority Data
Oct. 14, 2010 (KR) 10-2010-0100117

(51) Int. Cl. H01L 23/525; H01L 21/768

(52) U.S. Cl. 257/530; 438/600; 257/E23.147; 257/E21.592

(57) ABSTRACT

An anti-fuse of a semiconductor device and a method for manufacturing the same are disclosed. In order to achieve stable operation of the anti-fuse, a gate rupture prevention film is formed between a gate pattern and a source/drain junction region and a gate oxide film is formed at both ends of a lower edge of the gate pattern. Therefore, when applying a voltage, the overlapped gate oxide film is ruptured so that a current level is stabilized and the anti-fuse is stably operated.

### CROSS-REFERENCE TO RELATED APPLICATION

The priority of Korean patent application No. 10-2010-0100117 filed on 14 Oct. 2010, the disclosure of which is hereby incorporated in its entirety by reference, is claimed.

### BACKGROUND OF THE INVENTION

Embodiments of the present invention relate to an anti-fuse of a semiconductor device and a method for manufacturing the same.

In recent times, as information media such as computers have become widely used, technology of semiconductor devices has rapidly developed. Functionally, it is necessary for a semiconductor device to operate at a high speed and to have a high storage capacity. Therefore, technology for manufacturing semiconductor devices has been rapidly developed to improve integration degree, reliability, response speed, etc.

A process for manufacturing a semiconductor device includes a fabrication (FAB) process that forms cells that each have an integrated circuit by repeatedly forming a predetermined circuit pattern on a silicon substrate, and an assembly process that packages the substrate, including the cells, in a chip unit. An Electrical Die Sorting (EDS) process for testing electrical characteristics of cells formed over the substrate is performed between the FAB process and the assembly process.

The above-mentioned EDS process may determine whether or not the cells formed over the substrate are electrically defective. The EDS process is adapted to remove defective cells prior to execution of the assembly process, such that efforts and costs consumed in the assembly process may be reduced. In addition, the defective cells may be detected in early stages and reproduced through a repair process.

A detailed description of the repair process follows.

In order to increase the production yield of a semiconductor device, a redundant cell is added to substitute for a defective device or a defective circuit. A fuse for coupling the redundant cell to the integrated circuit is also added in the manufacturing process of the semiconductor device. In the repair process, a defective cell, detected by the test process is coupled to a redundant cell contained in the chip using the fuse, resulting in cell recovery. That is, the repair process cuts only specific fuses so that position information of the cells to be repaired can be generated.

However, although the process for repairing defective cells is performed at the wafer level, a 1-bit or a 2-bit defect may unexpectedly occur in normal chips at the wafer level even after execution of the packaging process, with an error rate of about 10%. Thus, a repair process after execution of the packaging process is necessary. Specifically, in an expensive Multi-Chip Package (MCP) for packaging a plurality of chips, the repair process must be performed after execution of the packaging process to reduce production costs.

However, since it is impossible to use a laser repair device after completion of the packaging process, a new fuse that is different from the fuse used in the repair process performed before the packaging process is needed. The fuse for use in a repair process performed after the packaging process will hereinafter be described in detail.

The fuse to be used after the packaging process is generally called an anti-fuse, and performs repairing through interconnection instead of disconnection. In contrast, the fuse to be used before the packaging process is designed to perform repairing through disconnection. That is, the term “anti-fuse” is derived from its functionality relative to the fuse used before the packaging process. The anti-fuse is electrically open in a normal state. However, if a high voltage is applied to the anti-fuse at a normal state and an insulator between conductors of the anti-fuse ruptures, the anti-fuse is short-circuited. The anti-fuse is formed in a periphery region and redundant cells for the anti-fuse are also formed in the periphery region. Such redundant cells are formed as SRAM cells that need not perform refreshing.

The anti-fuse has a variety of advantages. For example, the anti-fuse enables the repair process to be performed at a package level, increases a net die (number of unit cells per wafer), improves product characteristics, and overcomes dependency on device integration degree. Because of the above-mentioned characteristics and advantages of the anti-fuse, it is expected that the anti-fuse will be widely used in various technical fields. For the anti-fuse to be stably operated, it is necessary to make sure the insulator has been successfully ruptured.

### BRIEF SUMMARY OF THE INVENTION

Various embodiments of the present invention are directed to providing an anti-fuse of a semiconductor device and a method for manufacturing the same that substantially obviate one or more problems due to limitations and disadvantages of the related art.

An embodiment of the present invention relates to an anti-fuse of a semiconductor device and a method for manufacturing the same in which a gate rupture prevention film is formed between the gate pattern and a source/drain junction region and a gate oxide film is formed at both ends of a lower edge of a gate pattern, in order to achieve stable operations of the anti-fuse. Therefore, when applying a voltage, the overlapping gate oxide film is ruptured so that a current level is stabilized and the anti-fuse is stably operated.

In accordance with an aspect of the present invention, an anti-fuse for a semiconductor device includes a device isolation film for defining an active region over a semiconductor substrate; a gate pattern formed over the active region; a gate rupture prevention film pattern formed between the gate pattern and the active region; and a gate oxide film formed to overlap with both ends of a lower edge of the gate pattern.

The gate rupture prevention film pattern may include a nitride film.

The gate rupture prevention film pattern may be formed to be smaller than a width of the gate pattern.

The gate oxide film may have the same height as that of the gate rupture prevention film pattern.

The anti-fuse may further include a first contact plug coupled to the gate pattern; and a second contact plug coupled to the junction region.

In accordance with another aspect of the present invention, a method for manufacturing an anti-fuse of a semiconductor device includes forming a device isolation film defining an active region over a semiconductor substrate; forming a gate rupture prevention film pattern over the active region; forming a gate oxide film at an upper part of the active region and at a lateral surface of the gate rupture prevention film pattern; forming a gate pattern over the gate oxide film and the gate rupture prevention film pattern, wherein the gate oxide film is formed to overlap with both ends of a lower edge of the gate pattern; and forming a junction region by implanting impurities in the exposed active region.

The gate rupture prevention film pattern may be formed to be smaller than a width of the gate pattern.

The gate oxide film may have the same height as that of the gate rupture prevention film pattern.

The active region may be formed by ion implantation of P-type impurities.

The forming of the junction region may include performing ion implantation of N-type impurities in the active region.

The gate rupture prevention film pattern may include a nitride film.

The forming of the gate pattern may include forming a gate electrode layer over the device isolation film, the gate rupture prevention film pattern, and the gate oxide film; and etching the gate electrode layer and the gate oxide film using the gate mask until the active region and the device isolation film are exposed.

The gate electrode layer may be formed by ion implantation of N-type impurities.

The gate electrode layer may include polymer, tungsten (W), titanium (Ti) or tungsten nitride (WN).

The method may further include, after forming the junction region, forming a first contact plug coupled to the gate pattern; and forming a second contact plug coupled to the active region and the junction region.

In accordance with an aspect of the present invention, an anti-fuse for a semiconductor device includes a gate pattern formed over a substrate; and an anti-fuse insulation film formed between the gate pattern and the substrate, wherein the anti-fuse insulation film includes a first insulation film in a central region and a second insulation film extending from the first insulation film along a surface of the substrate, and wherein the first insulation film is configured to maintain its structural integrity at a given energy that is sufficient to rupture the second insulation film.

The first insulation film is configured to overlap with a junction region formed in the substrate.

The first insulation film is configured to isolate the junction region from the gate pattern in a normal state, and further configured for coupling the junction region to the gate pattern in a repair state.

The first insulation film includes a silicon nitride layer and the second insulation layer includes a silicon oxide layer.

It is to be understood that both the foregoing general description and the following detailed description of the present invention are exemplary and explanatory and are intended to provide further explanation of the invention as claimed.

### BRIEF DESCRIPTION OF THE DRAWINGS

FIGS. 1A to 1H are cross-sectional views illustrating an anti-fuse of a semiconductor device and a method for manufacturing the same according to embodiments of the present invention.

### DESCRIPTION OF EMBODIMENTS

Reference will now be made in detail to the embodiments of the present invention, examples of which are illustrated in the accompanying drawings. Wherever possible, the same reference numbers will be used throughout the drawings to refer to the same or like parts. An anti-fuse of a semiconductor device and a method for manufacturing the same according to embodiments of the present invention will hereinafter be described with reference to the appended drawings.

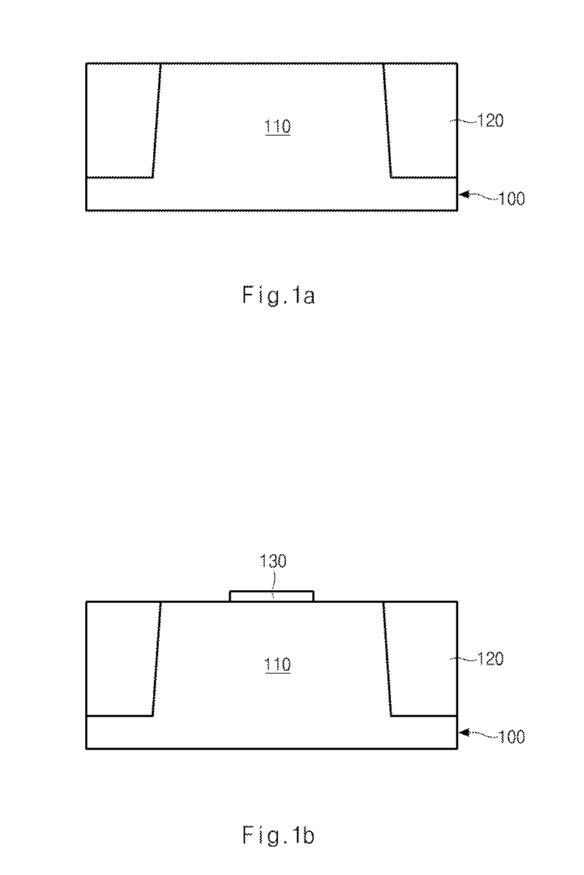

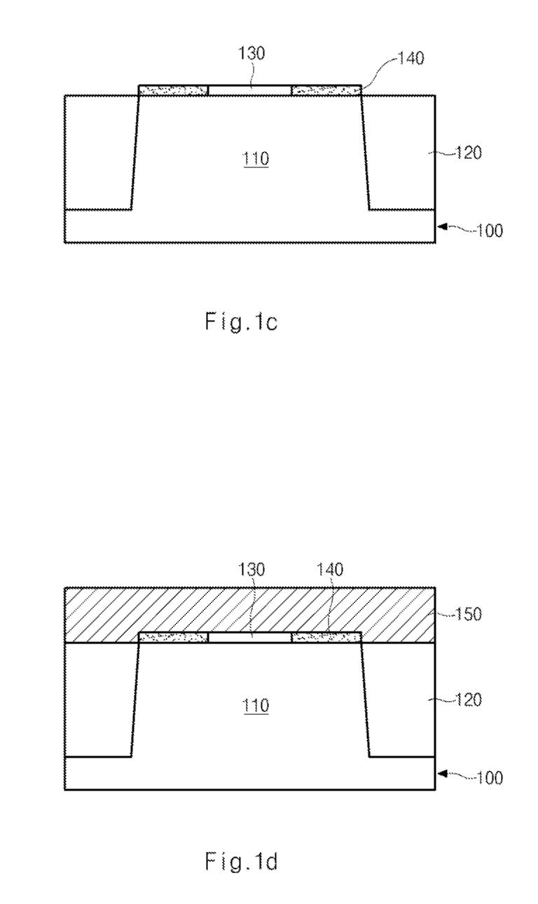

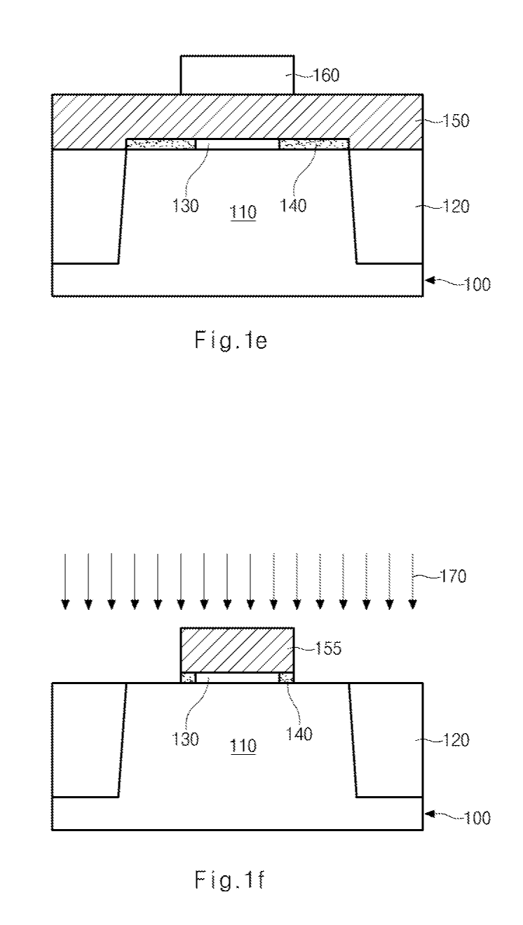

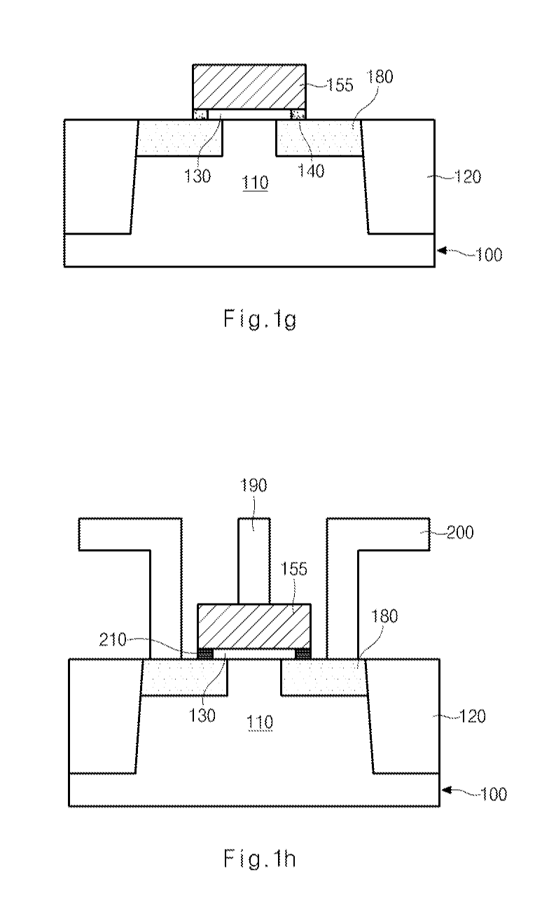

FIGS. 1A to 1H are cross-sectional views illustrating an anti-fuse of a semiconductor device and a method for manufacturing the same according to embodiments of the present invention.

Referring to FIG. 1A, a device isolation film 120 for defining an active region 110 is formed over a semiconductor substrate 100. The active region 110 may be formed by ion implantation of P-type impurities. The active region 110 is defined as a body part.

Referring to FIG. 1B, a gate rupture prevention film (not shown) is formed over the active region 110. In an embodiment, the gate rupture prevention film may include a nitride film, and may prevent gate rupture from occurring in a channel region.

Thereafter, the gate rupture prevention film is patterned so that a gate rupture prevention film pattern 130 is formed. In an embodiment, the gate rupture prevention film pattern 130 may have a pattern size smaller than that of the active region 110.

Referring to FIG. 1C, an oxidation process is performed on the exposed active region 110 so that a gate oxide film 140 is formed. In an embodiment, the gate rupture prevention film pattern 130 and the gate oxide film 140 are formed to have the same height over the active region 110.

Referring to FIG. 1D, a gate electrode layer 150 is formed over the device isolation film 120, the gate rupture prevention film pattern 130, and the gate oxide film 140.

Referring to FIG. 1E, after a photoresist film (not shown) is formed over the gate electrode layer 150, a photoresist pattern 160 is formed by an exposure and development process using a gate mask. In an embodiment, the photoresist pattern 160 may be smaller than the active region 110, but larger than the gate rupture prevention film pattern 130.

Referring to FIG. 1F, the gate electrode layer 150 and the gate oxide film 140 are etched using the photoresist pattern 160 as an etch mask until the active region 110 and the device isolation film 120 are exposed, so that the gate pattern 155 is formed. In an embodiment, the gate rupture prevention film pattern 130 may be formed between the gate pattern 155 and the active region 110, and the gate oxide film 140 may be formed to overlap with both ends of a lower edge of the gate pattern 155.

Thereafter, referring to FIG. 1G, ion implantation of impurities is performed in the gate pattern 155 and the exposed active region 110, so that a source/drain junction region 180 is formed in the exposed active region 110. In an embodiment, the source/drain junction region 180 may be formed by ion implantation of N-type impurities.

In this case, if the gate oxide film 140 is ruptured in the source/drain junction region 180, ohmic characteristics of current and voltage curves appear in the N-type gate pattern 155 and the N-type source/drain junction region 180, and thus gate resistance is reduced. However, if the gate oxide film 140 is ruptured in a channel region between the source/drain junction regions 180, diode characteristics of current and voltage curves appear in the N-type gate pattern 155 and the P-type semiconductor substrate 100, and thus gate resistance is increased. The gate rupture prevention film pattern 130 between the gate pattern 155 and the active region 110 can prevent this phenomenon. That is, when a voltage is applied to the anti-fuse in a subsequent process, the anti-fuse is ruptured in some regions (for example, the gate oxide film 140) that overlap with the source/drain junction region 180 so that the difference in current level is reduced and the anti-fuse can be stably operated.

Referring to FIG. 1H, if a gate rupture voltage is applied to the gate pattern 155, and a voltage is applied to the source/drain junction region 180, so that the gate oxide film 140 between the gate pattern 155 and the source/drain junction region 180 is ruptured, then a gate breakdown 210 occurs. In more detail, a first metal contact plug 190 coupled to the gate pattern 155 and a second metal contact plug 200 coupled to the source/drain junction region 180 are formed. In an embodiment, the first and second metal contact plugs 190 and 200 may be formed of tungsten (W), titanium (Ti) or titanium nitride (TiN). In this case, when voltages are applied through the first and second metal contact plugs 190 and 200, the gate oxide film 140 between the gate pattern 155 and the source/drain junction region 180 is ruptured, so that the difference in current level can be reduced and the anti-fuse can be stably operated.

As is apparent from the above description, in accordance with the above-mentioned embodiments of the present invention, in order to achieve stable operation of an anti-fuse, a gate rupture prevention film is formed between the gate pattern and the source/drain junction region, and a gate oxide film is formed at both ends of a lower edge of the gate pattern. Therefore, when applying a voltage, the overlapped gate oxide film is ruptured so that current level is stabilized and the anti-fuse is stably operated.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. An anti-fuse for a semiconductor device comprising:
a gate pattern formed over a substrate in an active region;
a gate rupture prevention film pattern formed between the gate pattern and the substrate; and
a gate oxide film extending from the gate rupture prevention film pattern and formed between the gate pattern and the substrate.

2. The anti-fuse according to claim 1, wherein the gate rupture prevention film pattern includes a nitride film.

3. The anti-fuse according to claim 1, wherein a width of the gate rupture prevention film pattern is formed to be smaller than a width of the gate pattern.

4. The anti-fuse according to claim 1, wherein a top of the gate oxide film is formed to substantially the same level as a top of the gate rupture prevention film pattern.

5. The anti-fuse according to claim 1, the anti-fuse further comprising:
a first contact plug coupled to the gate pattern; and
a second contact plug coupled to a junction region provided in the active region.

6. A method for manufacturing an anti-fuse of a semiconductor device comprising:
forming a gate rupture prevention film pattern over a substrate in an active region; forming a gate oxide film extending from the gate rupture prevention film pattern along a surface of the substrate;
forming a gate pattern over the gate oxide film and the gate rupture prevention film pattern, wherein the gate oxide film extends from the gate rupture prevention film pattern to an edge of the gate pattern; and
forming a junction region in the active region.

7. The method according to claim 6, wherein a width of the gate rupture prevention film pattern is smaller a width of the gate pattern.

8. The method according to claim 6, wherein a top of the gate oxide film is formed to substantially the same level as a top of the gate rupture prevention film pattern.

9. The method according to claim 6, wherein the active region is formed by ion implantation of P-type impurities.

10. The method according to claim 6, wherein the forming of the junction region includes:
performing ion implantation of N-type impurities in the active region.

11. The method according to claim 6, wherein the gate rupture prevention film pattern includes a nitride film.

12. The method according to claim 6, wherein the forming of the gate pattern includes:
forming a gate electrode layer over the gate rupture prevention film pattern, and the gate oxide film; and
etching the gate electrode layer and the gate oxide film using the gate electrode layer as a gate mask until the substrate in the active region is exposed.

13. The method according to claim 12, wherein the gate electrode layer is formed by ion implantation of N-type impurities.

14. The method according to claim 12, wherein the gate electrode layer includes polymer, tungsten (W), titanium (Ti), or tungsten nitride (WN).

15. The method according to claim 6, the method further comprising:
after forming the junction region,
forming a first contact plug coupled to the gate pattern; and
forming a second contact plug coupled to the junction region.

16. An anti-fuse for a semiconductor device comprising:
a gate pattern formed over a substrate; and
an anti-fuse insulation film formed between the gate pattern and the substrate,
wherein the anti-fuse insulation film includes a first insulation film in a central region and a second insulation film extending from the first insulation film along a surface of the substrate, and
wherein the first insulation film is configured to maintain its structural integrity at a given energy that is sufficient to rupture the second insulation film.

17. The anti-fuse for a semiconductor device of claim 16, wherein the first insulation film is configured to overlap with a junction region formed in the substrate.

18. The anti-fuse for a semiconductor device of claim 17, wherein the first insulation film is configured to isolate the junction region from the gate pattern in a normal state, and further configured for coupling the junction region to the gate pattern in a repair state.

19. The anti-fuse for a semiconductor device of claim 16, wherein the first insulation film includes a silicon nitride layer and the second insulation layer includes a silicon oxide layer.
